(19) United States
(12) Patent Application Publication
(10) Pub. No.: US 2016/0181070 A1
(43) Pub. Date: Jun. 23, 2016

(54) DEVICE FOR ION IMPLANTATION

(71) Applicant: ROTH & RAU AG, HOHENSTEIN-ERNSTTHAL (DE)

(72) Inventors: UWE SCHEIT, FRANKFURT (DE); JOACHIM MAI, NOBITZ (DE)

(21) Appl. No.: 15/058,808

(22) Filed: Mar. 2, 2016

Related U.S. Application Data
(62) Division of application No. 13/990,647, filed on May 30, 2013.

(30) Foreign Application Priority Data
Nov. 30, 2010 (DE) 102010060910.2

(51) Int. Cl. H01J 37/32

(52) U.S. Cl. CPC H01J 37/32412; H01J 2237/3365

(57) ABSTRACT

In an ion implantation device and a method for the ion implantation of a substrate, plasma having an ion density of at least 10¹⁰ cm⁻³, is generated by a plasma source in a discharge space. The discharge space is delimited in the direction of the substrate to be implanted by a plasma-delimiting wall. The plasma-delimiting wall being at a plasma potential, and a pressure in the discharge space is higher than the pressure in the space in which the substrate is situated in the ion implantation device. The substrate bears on a substrate support, with its substrate surface opposite the plasma-delimiting wall. The substrate and/or the substrate support are/is utilized as a substrate electrode, which is put at a high negative potential relative to the plasma that ions are accelerated from the plasma in the direction of the substrate and implanted into the substrate.

### CROSS-REFERENCE TO RELATED APPLICATION

This is a divisional application of application Ser. No. 13/990,647, filed May 30, 2013; which was a continuing application, under 35 U.S.C. §120, of International application PCT/IB2011/055148, filed Nov. 17, 2011; the application also claims the priority, under 35 U.S.C. §119, of German patent application No. DE 10 2010 060 910.2, filed Nov. 30, 2010; the prior applications are herewith incorporated by reference in their entireties.

### BACKGROUND OF THE INVENTION

### Field of the Invention

The present invention relates to an ion implantation device and a method for the ion implantation of at least one substrate, wherein a plasma having an ion density of at least 10¹⁰ cm⁻³, for example of 10¹⁰ cm⁻³ to 10¹² cm⁻³, is generated in the ion implantation device by means of a plasma source in a discharge space, wherein the discharge space is delimited in the direction of the substrate to be implanted by a plasma-delimiting wall having through openings spaced apart from one another, the plasma-delimiting wall being at plasma potential or a potential of a maximum of ±100 V, and the pressure in the discharge space is higher than the pressure in the space in which the substrate is situated in the ion implantation device; wherein the substrate bears on a substrate support, with its substrate surface opposite the plasma-delimiting wall; and wherein the substrate and/or the substrate support are/is utilized as substrate electrode, which is put at such a high negative potential relative to the plasma that ions are accelerated from the plasma in the direction of the substrate and implanted into the substrate.

U.S. Pat. No. 7,776,727 B2 discloses an ion immersion implantation method wherein a plasma is generated using an ICP (Inductively Coupled Plasma) discharge in a discharge space. A substrate to be implanted is situated in the plasma. The plasma is furthermore supplied with a process gas by means of a showerhead construction, the process gas being ionized in the plasma. The substrate bears on a substrate support, to which a high-frequency AC voltage is applied. Moreover, a chuck DC voltage is applied to the substrate support by means of a DC voltage source, by means of which chuck DC voltage ionized dopants in the plasma are accelerated in the direction of the surface of the substrate to be implanted and are implanted into the latter. During the ion implantation, the entire surface of the substrate to be implanted is directly connected to the plasma. The implantation is effected over the whole area into the surface of the substrate. The substrate support can be cooled during the ion implantation.

Alongside the above-described plasma immersion implantation installation for doping purposes, such installations can also be used for the targeted influencing of substrate properties, such as hardness or fracture strength. As described above, such installations operate without mass separation. The substrates or the workpieces are in direct, large-area contact with the plasma.

If it were desired to carry out a selective implantation of substrates with the aid of a plasma immersion implantation installation, in the known implantation techniques masks that delimit the regions to be doped are used on the substrates or between substrate and plasma. In this case, the masks used are bombarded with high-energy ions. Alongside the high thermal loading and the sputtering, correspondingly higher powers are required in this case for the acceleration of the ions. Therefore, in the case of plasma immersion ion implantation pulsed power supply units are often used for the acceleration voltage.

U.S. patent publication No. 2006/0019039 A1 discloses a device and a method of the generic type mentioned, wherein plasma immersion ion implantation is used. In this case, an implantation chamber enclosed on all sides is utilized, in which sub-chambers in the form of a plasma chamber and a process chamber are provided, between which is provided at least one grid by which ions are extracted from the plasma and are accelerated in the direction of the one substrate provided in the process chamber. In this case, both the at least one grid and the substrate can be put at a negative potential relative to the plasma. The plasma chamber and the process chamber are gas-technologically connected to one another and are evacuated by a single vacuum pump provided at the process chamber. During the implantation, the substrate to be implanted is situated within the implantation chamber enclosed on all sides. If the substrate is larger than the extent of the plasma chamber, the substrate bearing on a chuck integrated in the process chamber can be moved to and fro within the process chamber by means of an actuator arm below the plasma. The operation of the known implantation device is associated with substrate handling, wherein, by means of a wafer transfer robot, in each case only one substrate is introduced into the implantation chamber and is subsequently implanted in the implantation chamber after the latter has been closed off on all sides, and the substrate thereupon has to be brought out of the implantation chamber again after the latter has been opened. Therefore, the known installation is not suitable for implanting a multiplicity of substrates in an efficient time duration.

### SUMMARY OF THE INVENTION

Therefore, the object of the present invention is to provide a method and a device for ion implantation which enable an areal and also a selective ion implantation of a multiplicity of substrates in conjunction with the highest possible effectiveness.

The object is achieved, firstly, by means of a method of the generic type mentioned above, wherein the at least one substrate and/or the substrate support are/is moved on a substrate transport device, which runs opposite the plasma-delimiting wall, in a substrate transport direction toward the discharge space, along the discharge space continuously or discontinuously and past the discharge space, wherein the discharge space is separated with regard to its gas supply and gas extraction from the space in which the at least one substrate is situated during the ion implantation.

The present invention provides a new and improved method for the ion implantation of substrates. In this method, the at least one substrate to be implanted is not in direct contact with the plasma and furthermore is also not situated in the same vacuum reactor chamber enclosed toward the outside as the plasma. Instead, the at least one substrate is arranged outside the plasma, in which the substrate or the substrates can be moved past the plasma freely, in a substrate transport direction defined by the rectilinear course of the substrate transport direction, by means of the substrate transport device. In this case, in contrast to a handler principle, the substrates are not conveyed to and fro, but rather along a single basic substrate transport direction, that is to say in principle in a line, toward the discharge space, along the discharge space and finally away from the discharge space, wherein other substrates can subsequently be conveyed directly on this path.

The device according to the invention therefore enables an implantation of a multiplicity of substrates that can be moved past the plasma in a comparatively short time duration. In this case, the substrates can pass through a preprocessing directly before the implantation and/or pass through a postprocessing directly after the implantation, without complex substrate handling being necessary, since the substrates in this case can remain on one and the same substrate transport device and can be transported further by the latter. During the ion implantation, the substrates remain on one and the same substrate transport device. In this case, the transport plane is parallel to the plane of the plasma-delimiting wall. It is merely necessary to provide suitable interfaces between the implantation device and process modules disposed upstream and downstream, through which the substrates can be conveyed by the substrate transport device. By way of example, a belt transport device or a roller transport device can be used as substrate transport device. In this case, the substrates can bear or be held directly on the substrate transport device or on one or a plurality of substrate carrier(s) transported by the substrate transport device.

The method according to the invention thus makes it possible for a plurality of substrates provided at different positions on a substrate carrier to be moved past the discharge space by means of the substrate transport device and to be processed simultaneously or successively there—depending on their position on the substrate carrier.

In the method according to the invention, in accordance with one embodiment variant, the plasma source can also be moved relative to the at least one substrate during the ion implantation. The relative movement of substrate and plasma source can be utilized additionally alongside the above-described movement of the at least one substrate past the discharge space for the production of areal implantations or of specific implantation patterns.

Locks provided upstream and/or downstream of the discharge space in the substrate transport direction of the substrate transport device are especially suitable as interfaces between the ion implantation device and pre- and postprocessing chambers for the substrates. Through the locks situated between the process chambers, the substrates on the substrate transport device are transported into the ion implantation device and are transported out of the latter after ion implantation has been effected, without disadvantageous gas exchange taking place between the process chambers.

The plasma is delimited according to the invention by the plasma-delimiting wall, which is in contact with the plasma. The plasma-delimiting wall simultaneously forms a flow resistance for the discharge gas. Since the at least one substrate and/or the substrate support are/is put at a high negative potential relative to the plasma, the ions are accelerated through the through openings provided in the plasma-delimiting wall from the plasma in the direction of the substrate and are implanted into the substrate. During this implantation, the pattern formed by the through openings in the plasma-delimiting wall is mapped as a pattern of the implanted regions in the substrate. Through the choice of the thickness and the form of the structures or through openings in the plasma-delimiting wall, it is possible to adapt the plasma density to the respective requirements.

Ions of the desired doping element, such as phosphorus, arsenic, antimony, aluminum or boron, are present in the plasma. These ions only penetrate through the regions of the plasma-delimiting wall in which the through openings are provided, such that the geometry of the through openings is mapped in the substrate. The plasma-delimiting wall is at plasma potential or at a potential that differs only slightly from the plasma potential. In the case of the method according to the invention it is not necessary to use a mask which delimits the regions to be doped, as is customary in the prior art, on the substrate or in a region between the substrate and the plasma. Consequently, in the case of the ion implantation method according to the invention, a thermal loading or sputtering that arises with the use of masks is eliminated. Contamination of the substrate with mask material can be avoided as a result. Furthermore, the otherwise required additional partial steps for the production of masks on the substrate before the implantation are obviated.

Furthermore, the method according to the invention requires lower electrical powers of the voltage supply for accelerating the ions. The acceleration voltage can be reduced by comparison with the prior art. Although the method according to the invention for ion implantation is intended to be used, in particular, for doping substrates, the method can also be used, for example, for etching substrates, in which case all variants described with regard to ion implantation which are included in the present patent application can also be used when etching substrates.

Preferably, in the case of the method according to the invention, an ECR plasma source, an ICP plasma source or an ion source of the Finkelstein type is used as plasma source. By way of example, ECR plasmas can also advantageously be operated in an operating gas pressure range of less than 10⁻⁴ mbar to approximately 10⁻² mbar. These plasma sources are distinguished particularly by the fact that, at low pressures, they enable a high degree of ionization which, in particular in the method according to the invention, is suitable for the implantation of areal structures. The plasma sources proposed have particularly high plasma densities. It is thus possible, for example, to extract ion currents in the range of approximately 1 mA/cm² to approximately 10 mA/cm² from ICP plasma sources. Plasma sources of this type can be used to produce, for example, the ion implantation doses necessary in the case of solar wafers within a few seconds.

In the case of the method according to the invention, a suitable doping profile can also be established by using plasma sources which supply a high proportion of multiply charged ions. The multiply charged ions have, for the same acceleration voltage, a higher energy corresponding to the degree of ionization and penetrate more deeply into the substrate.

In order to be able to produce linear implantation regions or to be able to scan a substrate linearly during the ion implantation, it is favorable to use a linearly scalable plasma source as plasma source. Thus, by way of example, one possible application of the method according to the invention consists in producing, during the production of solar cells, n- and/or p-lines for the rear-side contact-connection of solar cells.

Furthermore, it is favorable if a plurality of individual plasma sources arranged alongside one another in the form of a line or a pattern is used as plasma source. A number of individual discharge spaces which are separate from one another but nevertheless arranged alongside one another are thereby made available, which can be utilized for producing different implantation patterns.

It has proved to be advantageous to apply a negative potential having a level of −5 kV to −100 kV to the substrate electrode. In this acceleration voltage range, the positively charged ions can be accelerated from the plasma very well in the direction of the substrate and advantageous penetration depths of the ions into the substrate are obtained.

In one preferred exemplary embodiment of the present invention, the negative potential is applied to the substrate electrode in the form of negative voltage pulses. As a result, the ions can be moved in a pulsed fashion from the plasma in the direction of the substrate. What can be achieved as a result is that the substrate is not heated as much, and the cooling of the substrate can thus be realized better.

However, it is also possible to generate the plasma itself in pulsed fashion. By this means, too, it is possible to achieve a lower thermal loading of the substrate. Furthermore, multiply charged ions can advantageously be generated by the pulsed plasma generation with high pulse powers, the acceleration of which ions to the substrate requires a lower acceleration voltage.

In one particularly advantageous possibility for configuration of the present invention, the pulsing of the substrate electrode and of the plasma is performed in a synchronized manner in-phase or phase-offset with respect to the one another. In this case, it is possible for the acceleration voltage pulses at the substrate electrode, on the one hand, and the pulsed activation of the plasma, on the other hand, to be implemented in a manner coordinated with one another, to be pulsed in a manner temporally offset with respect to one another, and/or for the pulsings to be performed in a manner overlapping one another. The synchronized pulsing of the substrate electrode and of the plasma has the advantage that, as a result, comparatively high voltage pulses can briefly be applied by comparison with conventional unpulsed operation, with which pulses a high power density can briefly be obtained, as a result of which it is possible to generate ions with higher charge states and it is thus also possible to set a higher ion density in the plasma. Thus, this procedure makes it possible to achieve, for example, briefly ion densities in the plasma of distinctly more than 10¹² cm⁻³, for example up to 10¹⁵ cm⁻³. Consequently, even with a low power overall, it is possible to obtain high penetration depths in the substrate to be implanted.

Preferably, the distance between the plasma-delimiting wall and the substrate electrode is set to be between 1 mm and 20 mm depending on the level of the negative potential at the substrate electrode. Thus, the distance between the substrate and the plasma-delimiting wall is approximately 3 mm to 6 mm given an acceleration voltage of 20 kV depending on the plasma density. In the case of higher acceleration voltages, the distance increases linearly with the voltage.

It is favorable to operate the plasma source with at least one dopant-containing gas or dopant-containing vapor. This includes phosphine (PH₃), diborane (B₂H₆), arsine (AsH₃), stibine (SbH₃), phosphorus chloride (PCl_{S}), boron bromide (BBr₃), arsenic chloride (AsCl₃), organometallic compounds comprising the dopants and/or dopants present as vapor.

In one advantageous exemplary embodiment of the present invention, an intermediate electrode having the same arrangement of through openings as in the plasma-delimiting wall is provided between the plasma-delimiting wall and the substrate electrode, wherein the intermediate electrode is put at a positive potential at a level of a maximum of 500 V. If such an intermediate electrode having an arrangement of the openings comparable to that in the plasma-delimiting wall in contact with the plasma is provided directly upstream of the substrate and if the wall is biased negatively relative to the substrate, an undesirable acceleration of secondary electrons in the direction of the plasma source can be prevented. The intermediate electrode acts as a potential barrier and thus as an electron deceleration grid. Moreover, in this embodiment, the intermediate electrode can be utilized in order to enable or to block the ion extraction from the discharge space, while the plasma is maintained in the discharge space. This has the advantage that time-consuming transient recovery processes of the plasma which are associated with the plasma being switched on and off can be avoided and the ion extraction from the plasma can nevertheless be performed in a suitably controlled manner, in order for example in combination with the movement of the at least one substrate along the discharge space to be able to produce specific implantation patterns on the at least one substrate.

In accordance with one embodiment variant of the method according to the invention, the positive potential is applied to the intermediate electrode in pulsed fashion. Consequently, the intermediate electrode can be used both for blocking and for opening the electron or ion passage in accordance with the pulsing performed. In this case, it is particularly favorable if here the pulsing of the intermediate electrode is performed in a synchronized manner with respect to the pulsing of the substrate electrode and/or the pulsing of the plasma in-phase or phase-offset with respect to one another.

Particularly advantageous possibilities for application of the method according to the invention arise if intermediate electrodes having locally different patterns of through openings for producing different implantation patterns are provided below a linearly scalable plasma source used as plasma source or below individual plasma sources used as plasma source.

It has proved to be particularly favorable to put the substrate support at a defined temperature. Thus, by way of example, the substrate can be positioned during the ion implantation on a cooled table or chuck, which is equipped with an electrostatic sample holder and as necessary with a helium or hydrogen supply for improving the heat transfer from the substrate to the cooled table or chuck. In this case, the substrate support can be used as a heat source or as a heat sink. The temperature regulation of the substrate support can be performed actively by means of liquid or gas as the heat carrier.

If substrate and plasma source are moved at constant velocity relative to one another, the implementation of homogeneous areal implantations is possible. Furthermore, the relative movement between substrate and plasma source can also be effected in a positively or negatively accelerated fashion and/or with controlled residence times of substrate and/or plasma source. Thus, by way of example, a matrix can be moved, as a result of which a spatially resolved doping can be produced by means of the ion implantation method according to the invention.

In a further variant of the method according to the invention, the distance between substrate and plasma source is changed during the relative movement of substrate and plasma source. The change in distance can be performed, for example, by means of a 3D movement of substrate and/or plasma source. In principle, it is also conceivable to permit the substrate and/or the plasma source to oscillate. By means of the changes in distance, it is possible, for example, to perform corrections during the ion implantation.

In a further embodiment of the method according to the invention, during the relative movement of substrate and plasma source, the direction of movement of substrate and/or plasma source can be reversed at least once, such that an interim movement of substrate to and fro relative to the plasma source is possible. In this case, however, the basic substrate transport direction is maintained.

Consequently, different charge carrier densities, charge states and/or time durations of the loading by the ion implantation can be set diversely by means of the targeted setting of the relative movement of substrate with respect to the plasma source.

In a likewise favorable embodiment of the present invention, a plurality of substrates is guided along in tracks below the plasma-delimiting wall with linear through openings. This procedure makes it possible to simultaneously process a plurality of substrates which is guided through in the tracks below the plasma-delimiting wall with the linear openings. In this case, as explained above, depending on the embodiment of the openings in the plasma-delimiting wall, the substrates can be moved continuously or with a regular halt below the plasma-delimiting wall, in order to dope the substrates in a defined manner.

In a further embodiment of the method according to the invention, the ion implantation is effected through at least one dielectric surface layer of the substrate. The implantation can be effected, for example, through suitable thin dielectric layers such as oxides or nitrides, such as are used for example for antireflection layers in the case of solar wafers, for setting a suitable doping profile.

It has proved to be particularly advantageous if after the ion implantation in the case of the method according to the invention, the ions implanted into the substrate are activated by means of a thermal treatment, preferably by means of an RTP (rapid thermal processing) or firing process. The implantation profile can thereby be adapted in accordance with the respective requirements.

The object of the present invention is furthermore achieved by means of an ion implantation device for the ion implantation of at least one substrate of the generic type mentioned above, wherein the discharge space is delimited in the direction of the substrate to be implanted by a plasma-delimiting wall having through openings spaced apart from one another, the plasma-delimiting wall being at plasma potential or a potential at a level of a maximum of ±100 V, wherein the discharge space is separated from the space in which the substrate is situated in the ion implantation device in such a way that a higher pressure can be set in the discharge space than in the space in which the substrate is situated; wherein the substrate can be placed on a substrate support, with its substrate surface opposite the plasma-delimiting wall; wherein the substrate and/or the substrate support can be put at such a high negative potential relative to the plasma that ions can be accelerated from the plasma in the direction of the substrate and can be implanted into the substrate; and wherein the at least one substrate and/or the substrate support can be moved on a substrate transport device, which runs opposite the plasma-delimiting wall, in a substrate transport direction toward the discharge space, along the discharge space continuously or discontinuously and past the discharge space, wherein the discharge space is separated with regard to its gas supply and gas extraction from the space in which the at least one substrate is situated during the ion implantation.

In the case of the ion implantation device according to the invention, an electrode having a multiplicity of through openings which simulate the desired structure is arranged between the substrate, in or on which at least one component is intended to be produced, and the discharge space, in which a plasma comprising ions of the desired doping element, such as phosphorus, arsenic, antimony, aluminum or boron, is present, through the plasma-delimiting wall. In this case, the plasma-delimiting wall acts like a mask, without being such a mask. The plasma-delimiting wall is at plasma potential or at a potential that differs only slightly from the plasma potential. The acceleration voltage for the implantation is applied between the plasma-delimiting wall and the at least one substrate arranged at a small distance in front of the plasma-delimiting wall. By means of the applied acceleration voltage, positive ions are extracted from the plasma and are accelerated to the substrate. In this way, the structure of the plasma-delimiting wall at the plasma potential is mapped in the substrate.

Furthermore, in the case of the ion implantation device according to the invention, one or a plurality of substrates can be moved freely past the discharge space. The space in which the substrates are situated is decoupled according to the invention from the discharge space with regard to the substrate support, the substrate transport and with regard to the gas supply and gas extraction. It is thereby possible to move substrates past the discharge space and to implant them in the process. This implantation can be effected both when the at least one substrate is at a standstill in the meantime and during the movement of the at least one substrate along and past the discharge space, which can be performed in each case continuously and also discontinuously. This affords not only the possibility of implanting a multiplicity of substrates in a short time, but also the option of providing pre- or postprocessing chambers for the substrates directly upstream and/or directly downstream of the implantation device, from and/or into which the substrates can be transported by means of the substrate transport device, without complex handling operations having to be carried out.

In this case, it is advantageous if, in accordance with one embodiment variant of the ion implantation device according to the invention, locks are provided upstream and downstream of the discharge space in the substrate transport direction of the substrate transport device, through which locks the at least one substrate on the substrate transport device can be transported into the ion implantation device and can be transported out of the latter after ion implantation has been effected.

In accordance with one advantageous embodiment of the present invention, the plasma source is an ECR plasma source, an ICP plasma source or an ion source of the Finkelstein type. Such plasma sources can make possible, at low pressures, high degrees of ionization which are required for the function of the ion implantation device according to the invention. Thus, high ion densities of 10¹⁰cm⁻³ to 10¹²cm⁻³ can be set in the plasma.

In order to be able to produce linear structures, it is particularly favorable to use a linearly scalable plasma source as plasma source.

Furthermore, it can be advantageous if the plasma source comprises a plurality of individual plasma sources arranged alongside one another in the form of a line or a pattern. In this case, the individual plasma sources form a plurality of discharge spaces which lie alongside one another and which can be utilized identically or differently.

In one advantageous embodiment of the ion implantation device according to the invention, the distance between the plasma-delimiting wall and the substrate electrode is between 1 mm and 20 mm depending on the negative potential at the substrate electrode. In most variants of the present invention, however, it suffices if the distance between the plasma-delimiting electrode and the substrate electrode is between 1 mm and 5 mm.

In accordance with one preferred configuration of the ion implantation device according to the invention, the plasma source has at least one feed for dopant-containing gas or dopant-containing vapor. As a result, the plasma source can be operated with gases or vapors which contain the desired dopant.

It has proved to be particularly advantageous if an intermediate electrode having the same arrangement of through openings as in the plasma-delimiting wall is provided between the plasma-delimiting wall and the substrate electrode, wherein the intermediate electrode can be put at a positive potential. Consequently, by means of the intermediate electrode, it is possible to form a potential barrier between the plasma and the substrate, which potential barrier can be used, in particular, as an electron deceleration grid for avoiding an undesirable acceleration of secondary electrons in the direction of the plasma source. Furthermore, the intermediate electrode can also be utilized for influencing the movement or acceleration of the ions from the plasma on to the substrate. Thus, the intermediate electrode can be put at specific positive potentials for example in a pulsed fashion. It is thereby possible for the intermediate electrode to be utilized as a switching electrode for opening and blocking the extraction of ions from the discharge space.

It is particularly advantageous if, in the case of the ion implantation device according to the invention, the substrate support can be operated as a heat source or heat sink for the substrate. The substrate can thereby be heated or cooled in a targeted manner. The heating or cooling can be performed actively by the use of liquid or gas as heat carrier.

In one favorable development of the method according to the invention, the pulsing of the intermediate electrode is performed in a synchronized manner with respect to the pulsing of the substrate electrode and/or the pulsing of the plasma in-phase or phase-offset with respect to one another. As a result, the voltage pulses applied to the intermediate electrode can be coordinated with the pulsing of the substrate electrode and/or the pulsing of the plasma in a targeted manner in order to obtain optimum implantation results in conjunction with comparatively low powers.

In accordance with one exemplary embodiment of the present invention, the through openings in the plasma-delimiting wall are embodied in linear or grid-shaped fashion. As a result, depending on the respective requirements, specific implantation patterns can be produced which can also be transferred areally to the substrate in the case of a relative movement of substrate with respect to plasma source.

As already mentioned, it is particularly favorable for the ion implantation device according to the invention to be embodied in such a way that the substrate and/or the plasma source can be moved relative to one another past one another during the ion implantation. In this case, as likewise explained above, there are a wide variety of possibilities for performing the relative movement of substrate with respect to plasma source.

In the case of a stationary arrangement of the substrates below the plasma-delimiting wall, the plasma region with approximately constant plasma conditions has to be sufficiently large. According to the invention, however, the implantation parameters can be realized by a targeted type of movement of the substrate relative to the plasma-delimiting wall in front of the plasma source.

In the case of the ion implantation device according to the invention, as a result of the necessarily higher total current in comparison with known implantation installations, the X-ray radiation occurring as a consequence also occurs with a higher dose. This requires more complex protective measures. Thus, one embodiment of the present invention provides for shielding the ion implantation device such that the X-ray radiation that arises during the process is reliably absorbed. By way of example, it is advantageous if the ion implantation device according to the invention has a housing that absorbs X-rays.

Other features which are considered as characteristic for the invention are set forth in the appended claims.

Although the invention is illustrated and described herein as embodied in a device for ion implantation, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 schematically shows one possible embodiment of an ion implantation device according to the invention in a sectional side view;

FIG. 2 schematically shows a further possible embodiment of the ion implantation device according to the invention in a sectional side view;

FIG. 3 schematically shows a plasma-delimiting wall with grid-type through openings of one embodiment of the ion implantation device according to the invention in a plan view;

FIG. 4 schematically shows a further component variant of the formation of through openings in a plasma-delimiting wall of one embodiment of the ion implantation device according to the invention in a plan view; and

FIG. 5 shows yet another embodiment variant of the formation of through openings in a plasma-delimiting wall of a further embodiment of the ion implantation device according to the invention in a plan view.

### DETAILED DESCRIPTION OF THE INVENTION

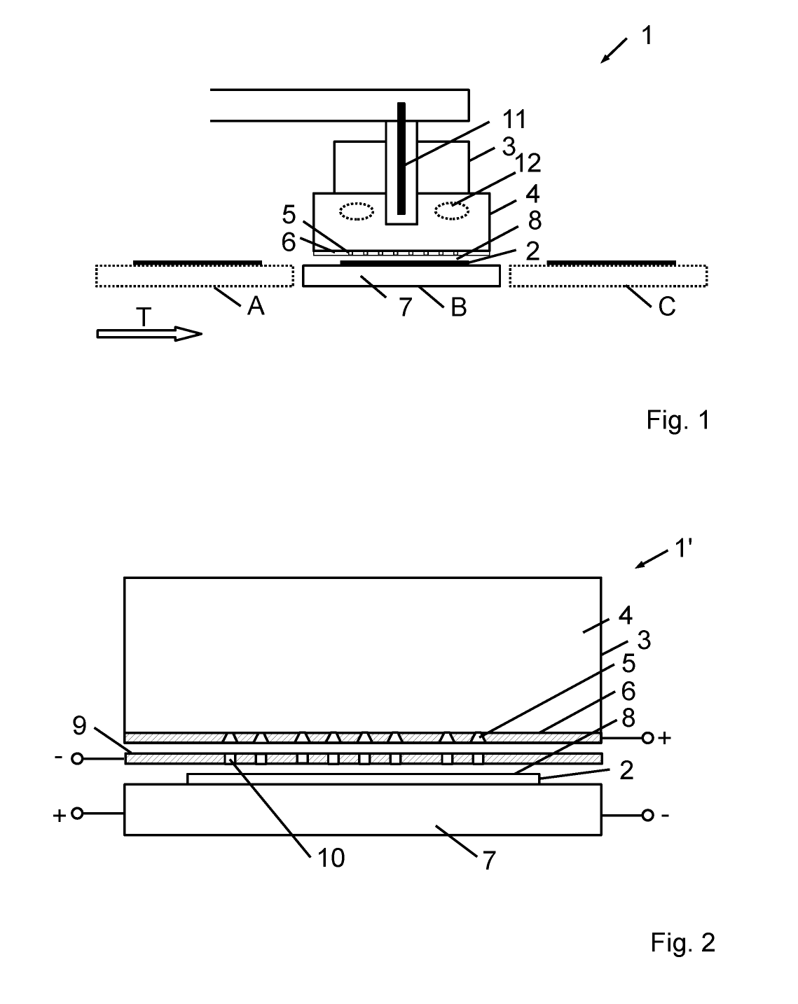

FIG. 1 schematically shows one possible embodiment of an ion implantation device 1 according to the invention in a sectional side view. The ion implantation device 1 shown serves for the ion implantation of at least one substrate 2, which bears on a substrate support 7 in the example illustrated. In principle, the device shown can also be used for etching substrates. The at least one substrate 2 and/or the substrate support can also bear on or be held by a substrate carrier.

The at least one substrate 2 is, for example, a substrate utilized for producing solar cells, such as a crystalline silicon substrate, for example. The substrate 2 can be already prepatterned. In particular, the substrate 2 can have a textured surface. Furthermore, it is possible for at least one thin dielectric layer to be provided on the substrate surface 8 of the substrate 2. By way of example, oxides or nitrides such as are used for example for antireflection layers in solar cell wafers come into consideration as thin dielectric layers. A suitable doping profile can be set with the aid of the dielectric layer material provided on the substrate 2.

In the exemplary embodiment illustrated, the substrate support 7, on which the substrate 2 bears, is a cooled substrate support that is not stationary relative to the ion implantation device 1. In other embodiment variants (not shown) of the present invention, the substrate support 7 can also be some other suitable substrate support which, for example, can also be heated. The cooling and/or heating of the substrate support 7 can be effected directly or indirectly. By way of example, heat carriers such as gases and/or liquids can be used in order to bring the substrate support 7 to a defined temperature.

The at least one substrate 2 is situated on a substrate transport device, by which the at least one substrate 2 can be moved through the implantation device. The substrate transport device can be, for example, a belt transport device or a roller transport device. In this case, the at least one substrate 2 can be transported directly by the substrate transport device or can bear on or be held by a substrate support such as a substrate carrier during transport. In the case where a substrate carrier is used, the substrates 2 can bear thereon in the form of a row, a column or a matrix.

The space in which the substrate transport device with the substrates 2 moved by the latter is provided according to the invention is not coupled to the discharge space 4 of the ion implantation device 1 with regard to the substrate support, the gas supply and the gas extraction. The substrates 2 can be conveyed into the space and out of the latter again independently of the plasma space. It is merely expedient to provide locks to other chambers which can be provided upstream and downstream of the ion implantation device 1 and in which the substrates 2 can be suitably pre- and/or postprocessed. In this case, the locks form suitable interfaces or exchange devices of substrates 2, without the substrates 2 in them having to be removed from the substrate transport device or transferred to some other substrate transport device.

In the example in FIG. 1, the substrate surface 8 is situated opposite a plasma source 3, which is an ECR plasma source in the exemplary embodiment shown. In other embodiment variants (not shown) of the present invention, it is also possible to use other suitable plasma sources according to the invention, such as, for example, ICP plasma sources or ion sources of the Finkelstein type. One prerequisite for the use of a specific plasma source 3 in the ion implantation device 1 according to the invention is that it can generate plasma having a high ion density of 10¹⁰cm⁻³ to 10¹²cm⁻³. Preferably, both singly charged and multiply charged ions of plasma generated in a discharge space 4 of the plasma source 3 are intended to be able to be generated with the aid of the plasma source 3. The discharge space 4 of the plasma source 3 is delimited in the direction of the substrate 2 by a plasma-delimiting wall 6. The plasma-delimiting wall 6 is either at plasma potential or a potential of a maximum of ±100V.

In the example shown, the substrate transport direction T of the substrate transport device runs parallel to the plasma-delimiting wall 6.

The plasma-delimiting wall 6 has through openings 5 spaced apart from one another, the arrangement or pattern of which is mapped during the implantation of the substrate 2 in the substrate surface 8 of the substrate 2.

By virtue of the fact that the discharge space 4 of the plasma source 3 is separated in particular gas-technologically by the plasma-delimiting wall 6 from the remaining space, in particular from the space in which the at least one substrate 2 is situated, the pressure in the discharge space 4 can be set to be higher than the pressure in the space in which the at least one substrate 2 is situated in the ion implantation device 1.

The at least one substrate 2 or the substrate support 7 on which the substrate 2 bears, and the plasma source 3 or at least the plasma-delimiting wall 6 of the plasma source 3 can be moved relative to one another in the exemplary embodiment shown in FIG. 1. In order to illustrate this, FIG. 1 illustrates various positions A, B, C for the substrate support 7 with the substrate 2 provided thereon. The relative movability between substrate 2 and plasma source 3 can be utilized in order to enable homogeneous, areal implantations of the substrate 2 during the movement of substrate 2 and plasma source 3 past one another.

During the ion implantation, the substrate 2 and/or the substrate support 7 serve(s) as substrate electrode, which is put at such a high negative potential relative to the plasma in the discharge space 4 that ions are accelerated from the plasma in the direction of the substrate 2 and are implanted into the substrate 2. By way of example, for this purpose, a negative potential having a level of −5 kV to -100 kV is applied to the substrate electrode, that is to say to the substrate 2 and/or to the substrate support 7. In this case, it is possible to apply the negative potential to the substrate electrode in the form of negative voltage pulses. On the other hand, it is also possible to generate the plasma in the discharge space 4 itself in a pulsed fashion. Furthermore, as explained above, the pulsed voltage supply of the substrate 2 and/or of the substrate support 7, on the one hand, and the pulsing of the plasma, on the other hand, can be performed in a synchronized manner in-phase or phase-offset with respect to one another, in order thereby to obtain a high penetration depth of ions in the substrate 2 even given a low power used, by virtue of briefly high voltage pulses and hence a briefly increased ion density in the plasma.

In the exemplary embodiment of the ion implantation device 1 according to the invention as illustrated in FIG. 1, the distance between the plasma-delimiting wall 6 and the substrate 2 is approximately 3 mm to 5 mm. Depending on the level of the negative potential at the substrate electrode, however, the distance between the plasma-delimiting wall 6 and the substrate 2 or the substrate electrode can be set between 1 mm and 20 mm according to the invention.

During the ion implantation, the plasma source 3 is operated with a dopant-containing gas or dopant-containing vapor. For this purpose, the plasma source 3 has at least one gas feed (not illustrated separately in FIG. 1) by which the gas or the vapor can be conducted into the discharge space 4 of the plasma source 3. By way of example, the dopant-containing gas or dopant-containing vapor used can be phosphine, diborane, arsine, stibine, phosphorus chloride, boron bromide, arsenic chloride, at least one organometallic compound comprising phosphorus, boron or arsenic and/or dopants present as vapor.

By means of the plasma source 3, the gas or the vapor is ionized in the discharge space 4. This gives rise to at least singly charged positive ions, which are accelerated by the negative potential present at the substrate electrode through the through openings 5 in the plasma-delimiting wall 6 in the direction of the at least one substrate 2 and are implanted into the at least one substrate 2 by the high acceleration voltage. As already mentioned above, in this case the structure of the plasma-delimiting wall 6, which is at the plasma potential or a low positive potential, is mapped in the at least one substrate 2. By means of a suitable choice of the parameters, a focusing of lines, for example, is possible as necessary.

If a direct mapping is not possible owing to the form of the structures of the through openings 5 in the plasma-delimiting wall 6, the desired geometry can be realized by a sequential implantation under a plurality of ion implantation devices 1 according to the invention, under individual plasma sources arranged in a row or in the form of a pattern, or by a multiple implantation in each case after a mechanical displacement or movement of the at least one substrate 2 relative to the plasma source 3. Thus, by a control of the movement of the at least one substrate 2 relative to the plasma source 3 for example in the case of linear structures of through openings 5 in the plasma-delimiting wall 6 in one process step, both a homogeneous doping and a doping of defined areas are possible.

In order to set a suitable doping profile it is possible to use a dielectric layer, such as, for example, an oxide or nitride used for antireflection layers in the case of solar wafers, on the substrate 2 and to perform the implantation through the dielectric layer.

A suitable doping profile can also be set by setting the plasma source 3 from FIG. 1 or replacing it by some other suitable plasma source 3 in such a way that the plasma source 3 supplies a high proportion of multiply charged ions. For the same acceleration voltage at the substrate electrode, the multiply charged ions have a higher energy corresponding to the degree of ionization and, consequently, penetrate more deeply into the substrate 2 during the ion implantation.

By means of the choice of the thickness and the form of the through openings 5 in the plasma-delimiting wall 6, the ion density of the ions extracted from the plasma can be adapted to the respective requirements.

Although not shown separately in FIG. 1, the ion implantation device 1 preferably has a shield that reliably absorbs the X-ray radiation that arises during the process. Thus, the ion implantation device 1 can have, for example, a housing that absorbs X-rays.

As shown in FIG. 1, the plasma-delimiting wall 6 should not be equated with an extraction electrode used in conventional immersion ion implantation devices. According to the invention, for ion extraction from the plasma in the discharge space 4, use is made of the substrate electrode, that is to say the substrate 2 or the substrate support 7, at which the high negative potential relative to the plasma is present. The space in which the plasma is situated is separated from the space in which the substrate 2 is situated by the plasma-delimiting wall 6, as a result of which it is possible to set a higher pressure in the discharge space 4 than in the space in which the substrate 2 is situated. The high ion density of at least 10¹⁰ cm⁻³or typically of 10¹⁰ cm⁻³to 10¹² cm⁻³ and also the low pressure in the space in which the substrate 2 is situated are an absolutely necessary precondition for the implementability of the ion implantation method according to the invention.

Irrespective of the fact that the basic construction illustrated schematically in FIG. 1 and containing plasma source 3 with plasma-delimiting wall 6, on the one hand, and substrate electrode 2, 7, on the other hand, suffices in order to be able to use the ion implantation method according to the invention, it can be advantageous to use the embodiment variant of the present invention as illustrated schematically in FIG. 2. Thus, FIG. 2 illustrates an ion implantation device 1′ according to the invention, wherein an intermediate electrode 9 is provided between the plasma-delimiting wall 6 and the substrate electrode 2, 7. Through openings 10 are provided in the intermediate electrode 9, the pattern of the through openings corresponding to the arrangement of through openings 5 in the plasma-delimiting wall 6. The intermediate electrode 9 can be put at a positive potential at a level of a maximum of 500V. An undesirable acceleration of secondary electrons in the direction of the plasma source 3 can be prevented by the intermediate electrode 9. Thus, the intermediate electrode 9 can be utilized as a switching electrode for opening and blocking the extraction of ions from the discharge space 4.

The positive potential can also be applied to the intermediate electrode 9 in a pulsed fashion. In this case, it is possible to perform the pulsing of the voltage supply of the intermediate electrode 9 in a synchronized manner with respect to the pulsing of the acceleration voltage present at the substrate 2 or the substrate support 7 and/or the pulsing of the plasma. In this case, the respective voltage pulses can be applied to the intermediate electrode 9, the substrate electrode 2, 7 and/or the plasma in-phase or phase-offset.

The further features of the ion implantation device 1′ illustrated in FIG. 2 correspond to those of the ion implantation device 1 from FIG. 1, reference being made to the above explanations with regards to these features.

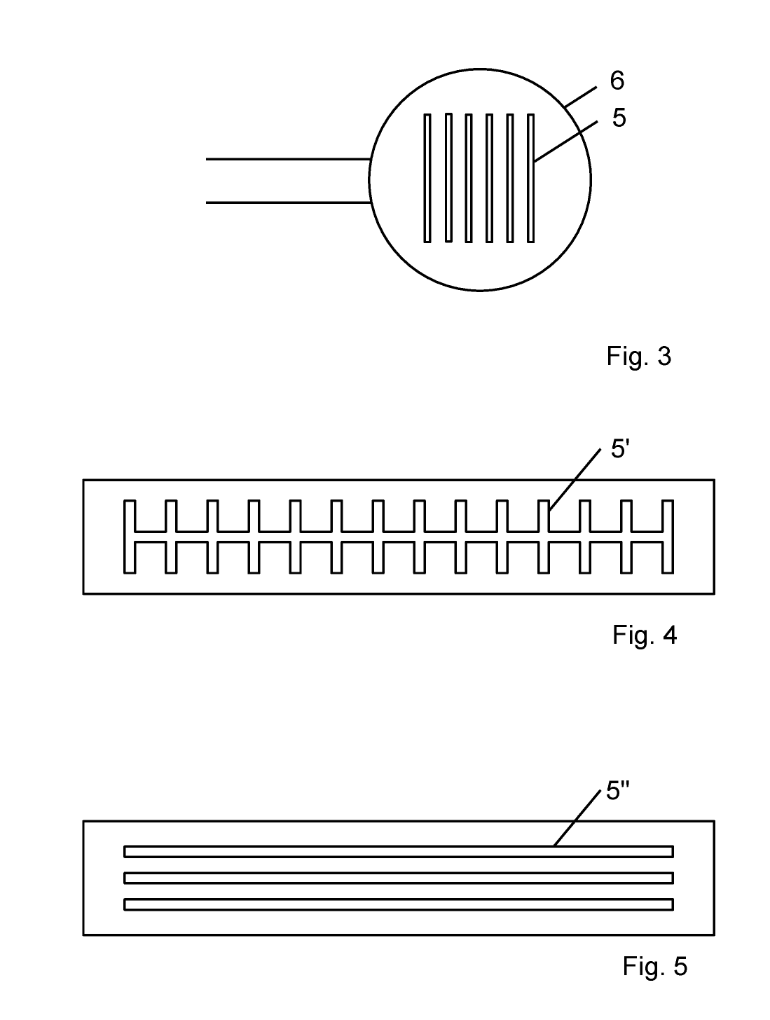

FIG. 3 schematically shows one possible embodiment variant of a plasma-delimiting wall 6 with grid-shaped through openings 5 in a plan view.

FIGS. 4 and 5 likewise schematically show possible embodiments of through openings 5′ and 5″, respectively, in a plasma-delimiting wall 6. Depending on the embodiment of the through openings 5, 5′ or 5″ in the plasma-delimiting wall 6, the substrates 2 can be moved continuously or with a regular halt below the plasma-delimiting wall 6 of the plasma source 3, in order to dope the substrates 2 in a defined manner. Thus, by way of example, the embodiment from FIG. 4 shows a grid-shaped arrangement of through openings 5′, while the embodiment from FIG. 5 shows a linear arrangement of through openings 5″. In this case, no limits are imposed, in principle, for the configuration of the through openings 5, 5′, 5″ in the plasma-delimiting wall 6. It is necessary, however, for the through openings 5, 5′, 5″ in the plasma-delimiting wall 6 to be formed in a manner spaced apart from one another.

1. An ion implantation device for ion implantation of at least one substrate, the ion implantation device comprising:
a plasma source having a discharge space, by which a plasma having an ion density of at least 10¹⁰ cm⁻³can be generated, the discharge space being delimited in a direction of the substrate to be implanted by a plasma-delimiting wall having through openings formed therein and spaced apart from one another, the plasma-delimiting wall being at plasma potential or a potential at a level of a maximum of ±100 V, the discharge space being separated from a space in which the substrate is situated in the ion implantation device such that a higher pressure can be set in the discharge space than in the space in which the substrate is situated;
a substrate support for receiving the substrate, the substrate when on said substrate support having a substrate surface opposite said plasma-delimiting wall, at least one of the substrate or said substrate support can be put at such a high negative potential relative to the plasma that ions can be accelerated from the plasma in a direction of the substrate and can be implanted into the substrate;
a substrate transport device, at least one of the at least one substrate or said substrate support can be moved on said substrate transport device, which runs opposite said plasma-delimiting wall, in a substrate transport direction toward said discharge space, along said discharge space continuously or discontinuously and past said discharge space, wherein said discharge space is separated with regard to a gas supply and gas extraction from the space in which the at least one substrate is situated during the ion implantation; and
an intermediate electrode having a same arrangement of through openings formed therein as in said plasma-delimiting wall, said intermediate electrode disposed between said plasma-delimiting wall and one of the substrate and said substrate support, wherein said intermediate electrode can be put at a positive potential and thus functioning as a switching electrode for opening and blocking an extraction of ions from said discharge space.

2. The ion implantation device according to claim 1, further comprising locks disposed upstream and downstream of said discharge space in the substrate transport direction of said substrate transport device, through said locks the at least one substrate on said substrate transport device can be transported into the ion implantation device and can be transported out of the ion implantation device after ion implantation has been effected.

3. The ion implantation device according to claim 1, wherein said plasma source is a linearly scalable plasma source.

4. The ion implantation device according to claim 1, wherein said plasma source has a plurality of individual plasma sources disposed alongside one another in the form of a line or a pattern.

5. The ion implantation device according to claim 1, wherein said through openings in said plasma-delimiting wall are embodied in a linear fashion or grid-shaped fashion.

6. The ion implantation device according to claim 1, further comprising a housing for absorbing X-rays.
